(19) United States
(12) Patent Application Publication
(10) Pub. No.: US 2026/0186076 A1
(43) Pub. Date: Jul. 2, 2026

(54) TEST DEVICE AND TEST METHOD THEREOF

(71) Applicant: Industrial Technology Research Institute, Hsinchu (TW)

(72) Inventors: Jin-Fu Li, Taoyuan City (TW); Yi-Chun Huang, New Taipei City (TW); Hong-Siang Fu, Taoyuan City (TW); Yung-Pin Lee, Hsinchu County (TW); Pei-Yun Lin, Taoyuan City (TW)

(73) Assignee: Industrial Technology Research Institute, Hsinchu (TW)

(21) Appl. No.: 19/002,711

(22) Filed: Dec. 27, 2024

(51) Int. Cl. G01R 31/58

(52) U.S. Cl. CPC G01R 31/58

(57) ABSTRACT

A test device and a test method thereof are provided. The test device includes a plurality of connection lines, a plurality of first test circuits, and a plurality of second test circuits. The first test circuits respectively generate a plurality of detection signals according to a plurality of first test data, and transmit the detection signals to the connection lines respectively. The second test circuits receive the detection signals through the connection lines, and the second test circuits compare the second test data with the detection signals to generate a plurality of test results.

### TECHNICAL FIELD

The disclosure relates to a connection line test technology, and more particularly, to a test device and a test method thereof.

### BACKGROUND

In the current packaging technology, chips usually communicate and transmit data through a large number of connection lines. Generally speaking, the connection lines between the chips will be formed by metal lines and bonding interfaces in the chips.

However, during a packaging process, the bonding interfaces of the connection lines between the chips are easily affected by thermomechanical stress, resulting in defects such as short circuits and open circuits. Short-circuit defects in the connection lines between the chips may cause bridging faults. In this case, operating quality of the chip will be affected by the defects.

In view of this, how to enable the chips to effectively test themselves or detect abnormal connection lines between the chips, so as to improve the operating quality of the chip, will be an important issue for those skilled in the art.

### SUMMARY

The disclosure provides a test device and a test method thereof, which may compare a plurality of test data with a plurality of detection signals through a plurality of test circuits to generate a plurality of test results, and test abnormal connection lines among the connection lines between chips according to the test results, thereby improving operating quality of the chip.

A test device in the disclosure includes a plurality of connection lines, a plurality of first test circuits, and a plurality of second test circuits. The first test circuits are respectively coupled to the connection lines. The first test circuits respectively generate a plurality of detection signals according to a plurality of first test data, and respectively transmit the detection signals to the connection lines. The second test circuits are respectively coupled to the connection lines, and receive the detection signals through the connection lines. The second test circuits respectively compare a plurality of second test data with the detection signals to generate a plurality of test results. The first test circuits and the second test circuits are arranged in an N*M matrix, and N and M are positive integers.

A test method of a test device in the disclosure includes the following. A plurality of connection lines are provided. A plurality of first test circuits are provided. A plurality of detection signals are respectively generated by the first test circuits according to a plurality of first test data, and the detection signals are respectively transmitted to the connection lines. A plurality of second test circuits are provided. The detection signals are received by the second test circuits through the connection lines, and a plurality of second test data are respectively compared with the detection signals by the second test circuits to generate a plurality of test results. The first test circuits and the second test circuits are arranged in an N*M matrix, and N and M are positive integers.

Based on the above, in the test device and the test method thereof according to the embodiments of the disclosure, the test device may test which of the connection lines is in the short-circuit state with the ground voltage or the power supply voltage in the chip according to the test results in the first test mode or the second test mode. In addition, the test device may test which of the connection lines has the fixed or bridging fault according to the test results in the third test mode. By observing test output results, it may be determined whether the connection line has the stuck-at-0 fault, the stuck-at-1 fault, the wired-AND bridging fault, the wired-OR bridging fault. In this way, the test device in the disclosure may effectively detect the abnormal connection lines between the chips, thereby improving the operating quality of the chip.

### BRIEF DESCRIPTION OF THE DRAWINGS

FIGS. 1A and 1B are schematic diagrams of a connection line between a first chip and a second chip according to an embodiment of the disclosure.

FIG. 2 is a schematic diagram of a test device according to an embodiment of the disclosure.

FIG. 3 is a circuit diagram of a test device according to an embodiment of FIG. 2 of the disclosure.

FIGS. 4A to 4B are respectively schematic diagrams of the test device shown in FIG. 3 operating in a first test mode and a second test mode according to the disclosure.

FIG. 5 is an operation flowchart of the test device in FIGS. 4A to 4B operating in the first test mode and the second test mode according to an embodiment of the disclosure.

FIGS. 6A to 6D are respectively schematic diagrams of the test device shown in FIG. 3 operating in a row test phase of a third test mode according to the disclosure.

FIGS. 7A to 7D are respectively schematic diagrams of the test device shown in FIG. 3 operating in a column test phase of the third test mode according to the disclosure.

FIG. 8 is an operation flowchart of the test device in FIGS. 6A to 6D and 7A to 7D operating in the row test phase and the column test phase of the third test mode according to an embodiment and of the disclosure.

FIG. 9 is a circuit diagram of a test device according to another embodiment of FIG. 2 of the disclosure.

FIG. 10 is a flowchart of a test method of a test device according to an embodiment of the disclosure.

### DETAILED DESCRIPTION OF DISCLOSED EMBODIMENTS

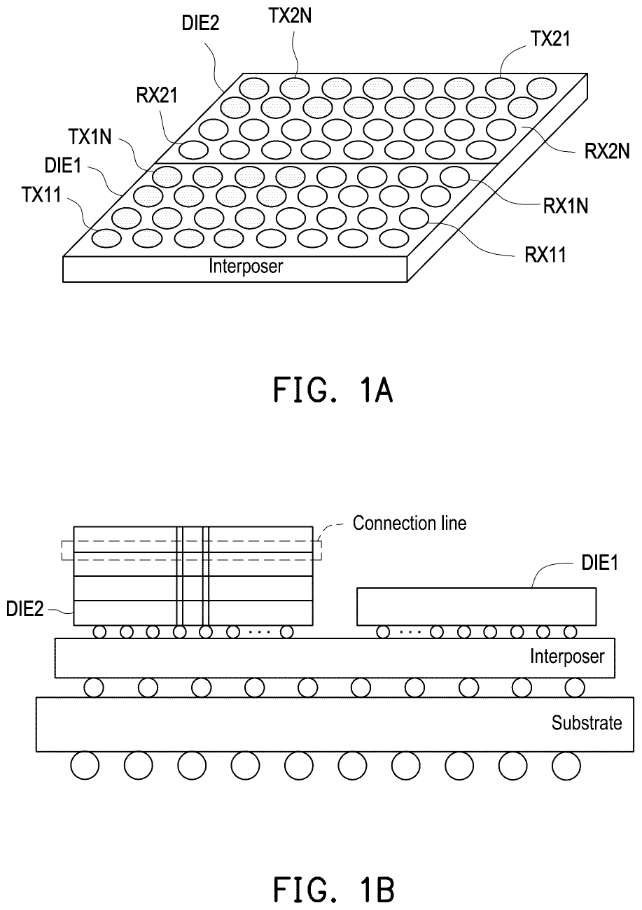

FIGS. 1A and 1B are schematic diagrams of a connection line between a first chip DIE1 and a second chip DIE2 according to an embodiment of the disclosure. Referring to FIG. 1A, in the embodiment of FIG. 1A, the first chip DIE1 and the second chip DIE2 may be connected through the connection line and connection points in an interposer, and the interposer may be disposed on a substrate. In addition, in the embodiment of FIG. 1B, the first chip DIE1 and the second chip DIE2 may also be applied to a connection line test between layers of chips in a three-dimensional chip (3D IC). The first chip DIE1 may be, for example, a memory controller, and the second chip DIE2 may be, for example, a stacked memory. However, the disclosure is not limited thereto.

Specifically, the first chip DIE1 includes a plurality of test circuits TX11 to TX1N (that is, first test circuits) and a plurality of test circuits RX11 to RX1N (that is, second test circuits), and the second chip DIE2 includes a plurality of test circuits TX21 to TX2N (that is, the first test circuits) and a plurality of test circuits RX21 to RX2N (that is, the second test circuits). In this embodiment, the test circuits TX11 to TX1N and the test circuits TX21 to TX2N may be used as transmitters of the chip, and the test circuits RX11 to RX1N and the test circuits RX21 to RX2N may be used as receivers of the chip.

For example, the test circuits TX11 to TX1N of the first chip DIE1 may be connected to a plurality of first connection points of the first chip DIE1 respectively, and the test circuits RX21 to RX2N of the second chip DIE2 may be connected to a plurality of second connection points of the second chip DIE2 respectively. In addition, the first connection points of the first chip DIE1 and the second connection points of the second chip DIE2 may be connected to each other through a plurality of connection lines P11 to PNM respectively.

Similarly, the test circuits TX21 to TX2N of the second chip DIE2 may be connected to a plurality of first connection points of the second chip DIE2 respectively, and the test circuits RX11 to RX1N of the first chip DIE1 may be connected to a plurality of second connection points of the first chip DIE1 respectively. In addition, the first connection points of the second chip DIE2 and the second connection points of the first chip DIE1 may be connected to each other through the connection lines respectively.

In this way, the first chip DIE1 and the second chip DIE2 may test or detect abnormal connection lines among the connection lines between the chips through the test circuits TX11 to TX1N of the first chip DIE1 and the corresponding test circuits RX21 to RX2N of the second chip DIE2 respectively or/and through the test circuits TX21 to TX2N of the second chip DIE2 and the corresponding RX11 to RX1N of the first chip DIE1 respectively, so as to improve operating quality of the chip.

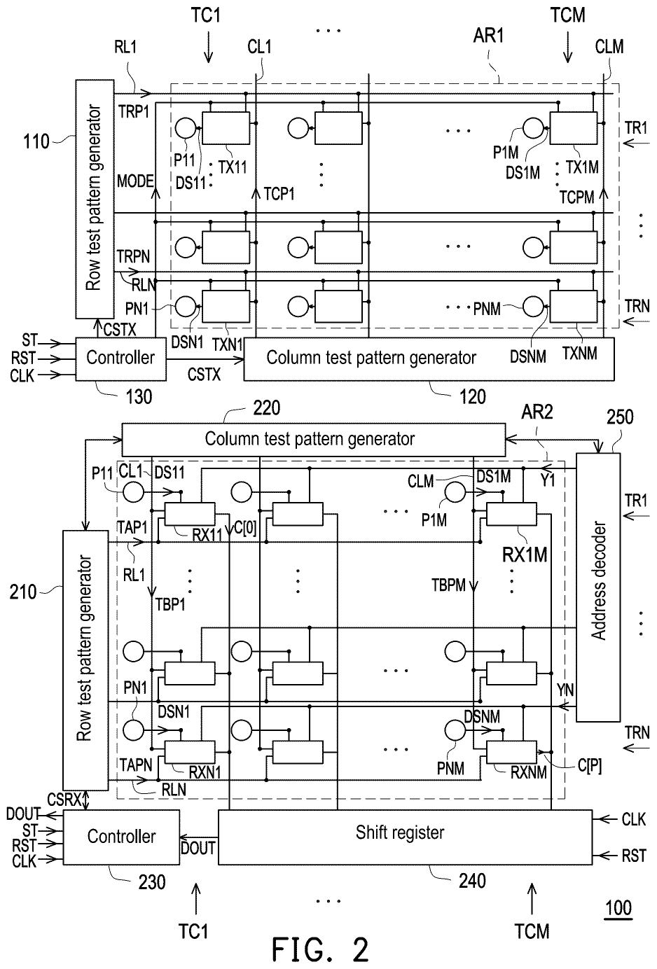

FIG. 2 is a schematic diagram of a test device 100 according to an embodiment of the disclosure. Referring to FIGS. 1A to 2 together, the test device 100 includes the connection lines P11 to PNM, a test circuit array AR1, a row test pattern generator 110, a column test pattern generator 120, and a controller 130. The test circuit array AR1 includes a plurality of test circuits TX11 to TXNM (that is, the first test circuits).

It is worth mentioning that in this embodiment, the test circuits TX11 to TXNM, the row test pattern generator 110, the column test pattern generator 120, and the controller 130 shown in FIG. 2 may be, for example, disposed in the first chip DIE1 shown in FIGS. 1A and 1B, so that the test circuits TX11 to TXNM may be tested in the first chip DIE1. The above-mentioned N and M may be positive integers.

The test circuits TX11 to TXNM may be (but are not limited to) arranged in an N*M matrix, and are disposed at intersections of a plurality of row test lines RL1 to RLN and a plurality of column test lines CL1 to CLM. The test circuits TX11 to TXNM may be arranged into a plurality of test rows TR1 to TRN and a plurality of test columns TC1 to TCM. The test circuits TX11 to TXNM are respectively coupled to the connection lines P11 to PNM, so as to perform relevant tests on the corresponding connection lines P11 to PNM.

In this embodiment, the controller 130 is coupled to the row test pattern generator 110, the column test pattern generator 120, and the test circuit array AR1. The controller 130 may receive a start signal ST, a reset signal RST, and a clock signal CLK. The controller 130 may generate a control signal CSTX to the row test pattern generator 110 and the column test pattern generator 120 according to the start signal ST, the reset signal RST, and the clock signal CLK, and generate a mode selection signal MODE to the test circuit array AR.

In this embodiment, the row test pattern generator 110 is coupled between the controller 130 and the row test lines RL1 to RLN. The row test pattern generator 110 may generate a plurality of test data TRP1 to TRPN to the test circuits TX11 to TXNM according to the control signal CSTX.

In this embodiment, the column test pattern generator 120 is coupled between the controller 130 and the column test lines CL1 to CLM. The column test pattern generator 120 may generate a plurality of test data TCP1 to TCPM to the test circuits TX11 to TXNM according to the control signal CSTX.

On the other hand, in the embodiment of FIG. 2, the test device 100 further includes a test circuit array AR2, a row test pattern generator 210, a column test pattern generator 220, a controller 230, a shift register 240, and an address decoder 250. The test circuit array AR2 includes a plurality of test circuits RX11 to RXNM (that is, the second test circuits).

It is worth mentioning that in this embodiment, the test circuits RX11 to RXNM, the row test pattern generator 210, the column test pattern generator 220, the controller 230, the shift register 240, and the address decoder 250 shown in FIG. 2 may be, for example, disposed in the second chip DIE2 shown in FIGS. 1A and 1B, so that the test circuits RX11 to RXNM may be tested in the second chip DIE2.

The test circuits RX11 to RXNM may be (but are not limited to) arranged in the N*M matrix, and are disposed at the intersections of the row test lines RL1 to RLN and the column test lines CL1 to CLM. The test circuits RX11 to RXNM may be arranged into the test rows TR1 to TRN and the test columns TC1 to TCM. The test circuits RX11 to RXNM are respectively coupled to the connection lines P11 to PNM to perform the relevant tests on the corresponding connection lines P11 to PNM. The test circuits RX11 to RXNM may be connected to the test circuits TX11 to TXNM respectively through the connection lines P11 to PNM.

In this embodiment, the controller 230 is coupled to the row test pattern generator 210, the column test pattern generator 220, the shift register 240, and the address decoder 250. The controller 230 may receive the start signal ST, the reset signal RST, and the clock signal CLK. The controller 230 may generate a control signal CSRX to the row test pattern generator 210, the column test pattern generator 220, and the address decoder 250 according to the start signal ST, the reset signal RST, and the clock signal CLK.

In this embodiment, the row test pattern generator 210 is coupled between the controller 230 and the row test lines RL1 to RLN. The row test pattern generator 210 may generate a plurality of test data TAP1 to TAPN to the test circuits RX11 to RXNM according to the control signal CSRX.

In this embodiment, the column test pattern generator 220 is coupled between the row test pattern generator 210 and the column test lines CL1 to CLM. The column test pattern generator 220 may generate a plurality of test data TBP1 to TBPM to the test circuits RX11 to RXNM according to the control signal CSRX.

In this embodiment, the address decoder 250 is coupled to the column test pattern generator 220 and the test circuits RX11 to RXNM. The address decoder 250 may generate a plurality of control signals Y1 to YN to the test circuits RX11 to RXNM according to the control signal CSRX, so as to control the test circuits on the corresponding test rows to sequentially generate test results C[0] to C[P].

In this embodiment, the shift register 240 is coupled between the test circuits RX11 to RXNM and the controller 230. The shift register 240 may receive the reset signal RST and the clock signal CLK, sequentially receive and transmit the test results C[0] to C[P] of the test circuits RX11 to RXNM according to the reset signal RST and the clock signal CLK, and output a corresponding test result DOUT to the controller 230.

Regarding operation actions of the test device 100, specifically, in the test device 100 shown in FIG. 2, the test circuits TX11 to TXNM may generate a plurality of detection signals DS11 to DSNM respectively according to the test data TRP1 to TRPN, the test data TCP1 to TCPN, and the mode selection signal MODE, and transmit the detection signals DS11 to DSNM to the connection lines P11 to PNM respectively.

For example, the test circuit TX11 may receive the mode selection signal MODE, the test data TRP1, and the test data TCP1, and the test circuit TX11 may generate the detection signal DS11 according to the test data TRP1 and the test data TCP1 based on the mode selection signal MODE. Then, the test circuit TX11 may transmit the detection signal DS11 to the corresponding connection line P11, and transmit the detection signal DS11 to the corresponding test circuit RX11 through the connection line P11. Operation methods of the remaining test circuits TX12 to TXNM may be derived by analogy.

On the other hand, the test circuits RX11 to RXNM may receive the detection signals DS11 to DSNM from the test circuits TX11 to TXNM through the connection lines P11 to PNM respectively. Then, the test circuits RX11 to RXNM may compare the test data TAP1 to TAPN and the test data TBP1 to TBPM with the detection signals DS11 to DSNM to generate the test results C[0] to C[P] respectively.

For example, the test circuit RX11 may receive the detection signal DS11 through the corresponding connection line P11, and receive the test data TAP1 and the test data TBP1 from the row test line RL1 and the column test line CL1 respectively. Then, the test circuit RX11 may compare the detection signal DS11 with the test data TAP1 and TBP1 to generate the test result C[0]. Operation methods of the remaining test circuits RX12 to RXNM may be derived by analogy.

On the other hand, the shift register 240 may sequentially output the test results C[0] to C[P] of the test circuits RX11 to RXNM according to a timing state of the clock signal CLK. In other words, since the test results C[0] to C[P] may respectively correspond to operating states of the connection lines P11 to PNM (for example, the test result C[0] may correspond to the connection line P11, and the test result C[P] may correspond to the connection line PNM), the test device 100 may determine or detect which of the connection lines P11 to PNM has an abnormal state from the test results C[0] to C[P], so that a back-end system or a circuit may handle the abnormal connection line accordingly.

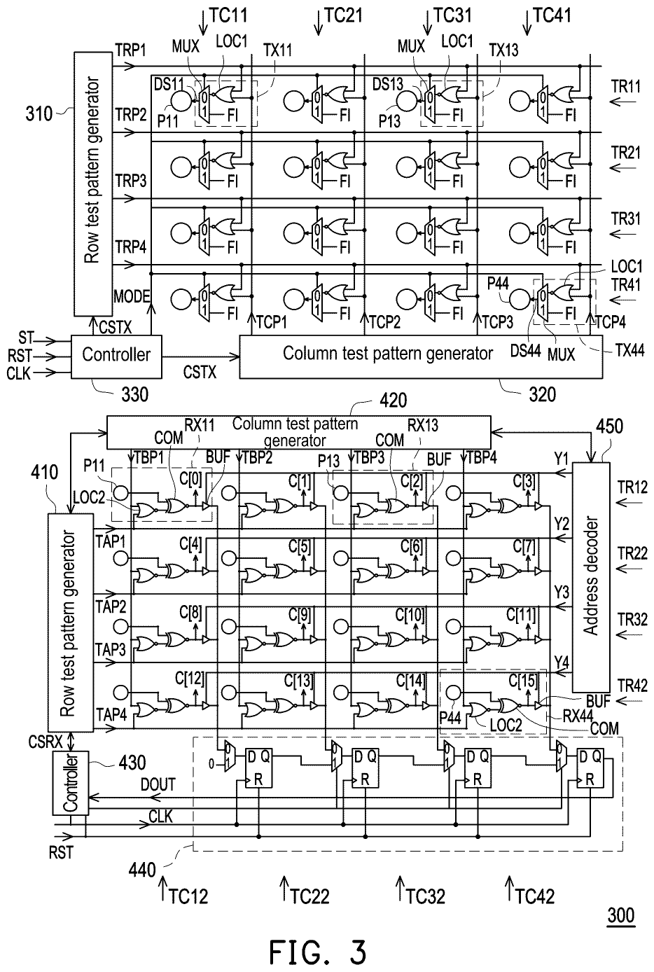

FIG. 3 is a circuit diagram of a test device 300 according to an embodiment of FIG. 2 of the disclosure. Referring to both FIGS. 2 and 3, in this embodiment, the test device 300 includes the connection lines P11 to P44, the test circuit array AR1, a row test pattern generator 310, a column test pattern generator 320, and a controller 330. The test circuit array AR1 is arranged in a 4*4 matrix, and the test circuit array AR1 includes the test circuits TX11 to TX44 (that is, the first test circuits). The test circuit array AR1 has a plurality of test rows TR11 to TR41 and a plurality of test columns TC11 to TC41.

In particular, operating functions and coupling methods of the test circuits TX11 to TX44, the row test pattern generator 310, the column test pattern generator 320, and the controller 330 shown in FIG. 3 are respectively the same as or similar to operating functions and coupling methods of the test circuits TX11 to TXNM, the row test pattern generator 110, the column test pattern generator 120, and the controller 130 shown in FIG. 2. Therefore, the test circuits TX11 to TX44, the row test pattern generator 310, the column test pattern generator 320, and the controller 330 shown in FIG. 3 may be derived by analogy with reference to related descriptions of the test circuits TX11 to TXNM, the row test pattern generator 110, the column test pattern generator 120, and the controller 130 mentioned in FIG. 2. Therefore, the same details will not be repeated in the following. In addition, in FIGS. 2 and 3, the same or similar elements or components will be denoted by the same or similar reference numerals.

Referring to FIG. 3, in this embodiment, each of the test circuits TX11 to TX44 of the test circuit array AR1 may include a logic gate LOC1 and a multiplexer MUX. In the embodiment of FIG. 3, the logic gate LOC1 may be implemented by an NOR gate.

For the convenience of description, the test circuit TX11 is taken as an example for description here, and the operation methods of the remaining test circuits TX12 to TX44 may be derived by analogy. For example, the test circuit TX11 includes the logic gate LOC1 and the multiplexer MUX. A first input end of the logic gate LOC1 may receive the test data TRP1, and a second input end of the logic gate LOC1 may receive the test data TCP1. A control end of the multiplexer MUX may receive the mode selection signal MODE. A first input end of the multiplexer MUX may be coupled to an output end of the logic gate LOC1. A second input end of the multiplexer MUX may receive a reference signal FI. An output end of the multiplexer MUX may be coupled to the corresponding connection line P11.

Furthermore, in the test circuit TX11 of the test device 300, the logic gate LOC1 may perform NOR computation on the test data TRP1 and TCP1, and correspondingly output the detection signal DS11 according to a computation result. Then, the multiplexer MUX may select and transmit the detection signal DS11 to the corresponding connection line P11 according to the mode selection signal MODE.

On the other hand, in the embodiment of FIG. 3, the test device 300 further includes the test circuit array AR2, a row test pattern generator 410, a column test pattern generator 420, a controller 430, a shift register 440, and an address decoder 450. The test circuit array AR2 includes the test circuits RX11 to RX44 (that is, the second test circuits). The test circuit array AR2 has a plurality of test rows TR12 to TR42 and a plurality of test columns TC12 to TC42.

In particular, operating functions and coupling methods of the test circuits RX11 to RX44, the row test pattern generator 410, the column test pattern generator 420, the controller 430, the shift register 440, and the address decoder 450 shown in FIG. 3 are respectively the same as or similar to operating functions and coupling methods of the test circuits RX11 to RXNM, the row test pattern generator 210, the column test pattern generator 220, the controller 230, the shift register 240, and the address decoder 250 shown in FIG. 2. Therefore, the test circuits RX11 to RX44, the row test pattern generator 410, the column test pattern generator 420, the controller 430, the shift register 440, and the address decoder 450 shown in FIG. 3 may be derived by analogy with reference to related descriptions of the test circuits RX11 to RXNM, the row test pattern generator 210, the column test pattern generator 220, the controller 230, the shift register 240, and the address decoder 250 mentioned in FIG. 2. Therefore, the same details will not be repeated in the following. In addition, in FIGS. 2 and 3, the same or similar elements or components will be denoted by the same or similar reference numerals.

Referring to FIG. 3, in this embodiment, each of the test circuits RX11 to RX44 of the test circuit array AR2 may include a logic gate LOC2, a comparator COM, and a buffer BUF. In the embodiment of FIG. 3, the logic gate LOC2 may be implemented by the NOR gate, and the comparator COM may be implemented by an XNOR gate.

For the convenience of description, the test circuit RX11 is taken as an example for description here, and the operation methods of the remaining test circuits RX12 to RX44 may be derived by analogy. For example, the test circuit RX11 includes the logic gate LOC2, the comparator COM, and the buffer BUF. A first input end of the logic gate LOC2 may receive the test data TBP1, and a second input end of the logic gate LOC2 may receive the test data TAP1. A first input end of the comparator COM may be coupled to the corresponding connection line P11, and receives the detection signal DS11 from the test circuit TX11 through the connection line P11. A second input end of the comparator COM may be coupled to an output end of the logic gate LOC2. An input end of the buffer BUF is coupled to an output terminal of the comparator COM, and an output end of the buffer BUF is coupled to the shift register 440.

Furthermore, in the test circuit RX11 of the test device 300, the logic gate LOC2 may perform the NOR computation on the test data TAP1 and TBP1, and correspondingly generate an output signal according to the computation result. Then, the comparator COM may perform XNOR computation on the output signal and the detection signal DS11 to generate the test result C[0] to the buffer BUF. In addition, the buffer BUF may provide the test result C[0] to the shift register 440 according to the control signal Y1.

On the other hand, in the embodiment of FIG. 3, the shift register 440 includes a plurality of D-type flip-flops and a plurality of multiplexers connected in series. Each of the D-type flip-flops may sequentially output the test results C[0] to C[15] of the test circuit RX11 to RX44 according to the clock signal CLK and reset signal RST, and transmit the corresponding test result DOUT to the controller 430.

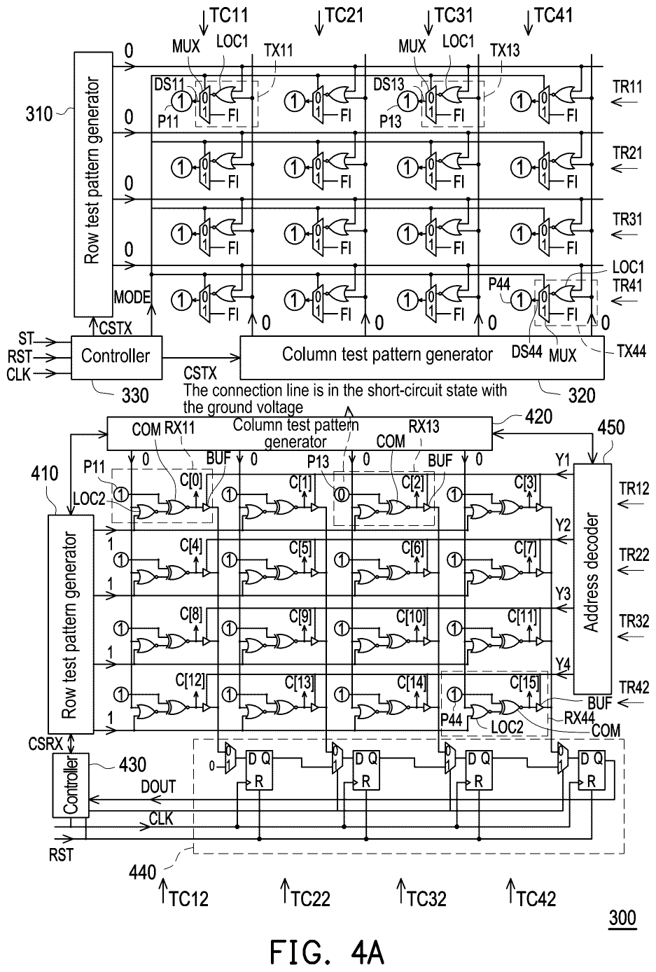

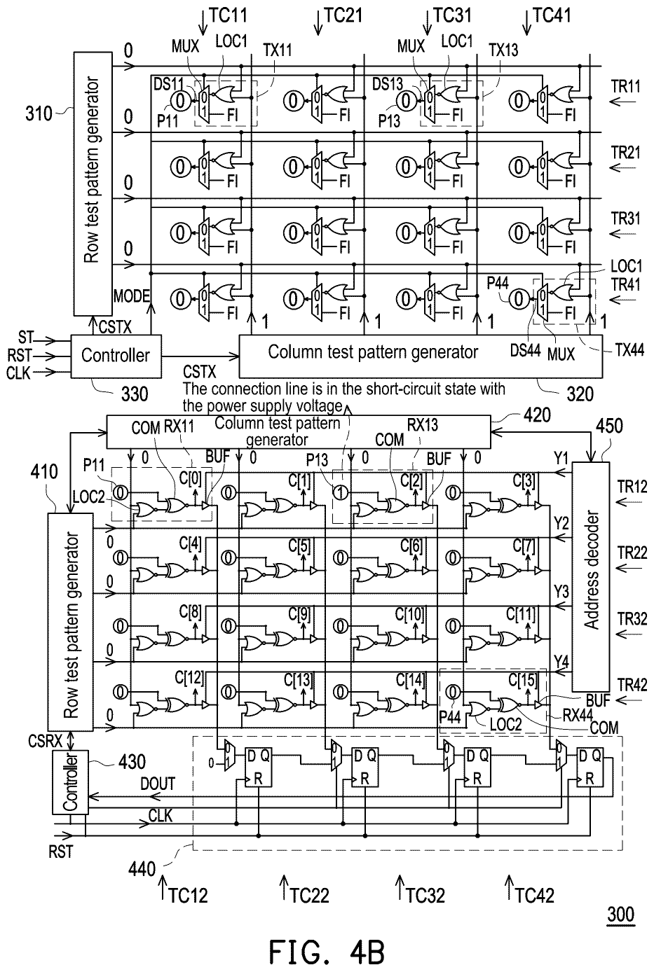

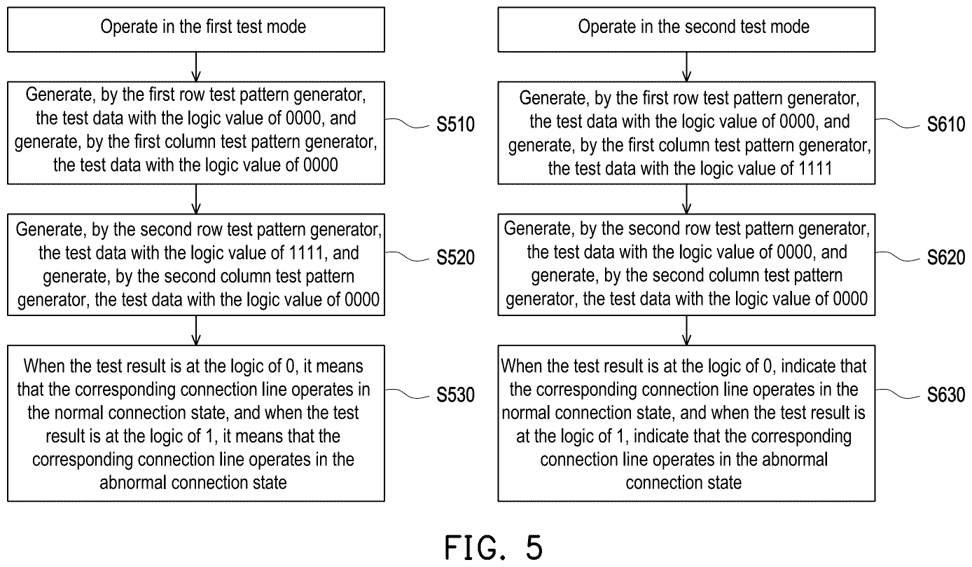

FIGS. 4A to 4B are respectively schematic diagrams of the test device 300 shown in FIG. 3 operating in a first test mode and a second test mode according to the disclosure, and FIG. 5 is an operation flowchart of the test device 300 in FIGS. 4A to 4B operating in the first test mode and the second test mode according to an embodiment of the disclosure.

It should be noted that the test device 300 shown in FIGS. 4A and 4B is the same as or similar to the test device 300 shown in FIG. 3. FIG. 4A shows a situation state when the test circuits TX11 to TX44 and the test circuits RX11 to RX44 of the test device 300 operate in the first test mode, and FIG. 4B shows a situation state when the test circuits TX11 to TX44 and the test circuits RX11 to RX44 of the test device 300 operate in the second test mode.

In this embodiment, in the first test mode, the test device 300 may test which of the connection lines P11 to P44 is in a short-circuit state with a ground voltage in the chip according to the test results C[0] to C[15]. In addition, in the second test mode, the test device 300 may test which of the connection lines P11 to P44 is in the short-circuit state with a power supply voltage in the chip according to the test results C[0] to C[15].

In addition, the test device 300 may perform operation actions of the first test mode according to steps S510 to S530 in FIG. 5, and the test device 300 may perform operation actions of the second test mode according to steps S610 to S630 in FIG. 5.

Referring to both FIGS. 4A and 5, in the embodiment of FIG. 4A, each of the test data TRP1 to TRP4, the test data TCP1 to TCP4, the test data TAP1 to TAP4, and the test data TBP1 to TBP4 may include a plurality of bits.

Specifically, in step S510, when the row test pattern generator 310 generates the test data TRP1 to TRP4 with a logic value of 0000 according to the control signal CSTX, and the column test pattern generator 320 generates the test data TCP1 to TCP4 with the logic value of 0000 according to the control signal CSTX, the test circuits TX11 to TX44 of the test device 300 may operate in the first test mode.

In the first test mode, the logic gates LOC1 in the test circuits TX11 to TX44 may respectively generate the detection signals DS11 to DS44 with a logic value of 1 according to the test data TRP1 to TRP4 with the logic value of 0000 and the test data TCP1 to TCP4 with the logic value of 0000 respectively. In addition, the multiplexers MUX in the test circuits TX11 to TX44 may select and transmit the detection signals DS11 to DS44 with the logic value of 1 to the corresponding connection lines P11 to P44 respectively based on the mode selection signal MODE.

On the other hand, in step S520, when the row test pattern generator 410 generates the test data TAP1 to TAP4 with a logic value of 1111 according to the control signal CSRX, and the column test pattern generator 420 generates the test data TBP1 to TBP4 with the logic value of 0000 according to the control signal CSRX, the test circuits RX11 to RX44 of the test device 300 may operate in the first test mode.

In the first test mode, the comparators COM in the test circuits RX11 to RX44 may respectively receive the detection signals DS11 to DS44 with the logic value of 1 through the corresponding connection lines P11 to P44.

For the convenience of description, the test circuit RX11 is taken as an example for description here, and the operation methods of the remaining test circuits RX12 to RX44 may be derived by analogy. For example, in this embodiment, the logic gate LOC2 of the test circuit RX11 may generate an output signal with a logic value of 0 according to the test data TAP1 with the logic value of 1 and the test data TBP1 with the logic value of 0. Then, the comparator COM of the test circuit RX11 may generate the test result C[0] with the logic value of 0 according to the output signal with the logic value of 0 and the detection signal DS11 with the logic value of 1.

It is worth mentioning that in step S530, when the test result C[0] of the test circuit RX11 is the logic value of 0, it means that in a transmission path where the test circuit TX11 transmits the detection signal DS11 to the test circuit RX11 through the connection line P11, the connection line P11 does not have the abnormal state, so that the detection signal DS11 may be maintained at a logic of 1.

In this case, in the first test mode, the test device 300 may test or determine that the corresponding connection line P11 operates in a normal connection state according to the test result C[0] with the logic value of 0.

Relatively, as shown in FIG. 4A, it is assumed that when in a transmission path where the test circuit TX13 transmits the detection signal DS13 to the test circuit RX13 through the connection line P13, the connection line P13 has the abnormal state (that is, the connection line P13 and the ground voltage in the chip are in the short-circuit state), causing a logic value of the detection signal DS13 to change from the original logic value of 1 to the logic value of 0, the test circuit RX13 will generate the test result C[2] with the logic value of 1 according to the detection signal DS13, the test data TAP3, and the test data TBP3.

In this case, the test device 300 may determine that the corresponding connection line P13 operates in an abnormal connection state according to the test result C[2] with the logic value of 1 (step S530). In other words, in the first test mode, the test device 300 may test or determine that the corresponding connection line P13 and the ground voltage in the chip are in the short-circuit state (that is, stuck-at-0) according to the test result C[2] with the logic value of 1.

On the other hand, referring to both FIGS. 4B and 5, in the embodiment of FIG. 4B, each of the test data TRP1 to TRP4, the test data TCP1 to TCP4, the test data TAP1 to TAP4, and the test data TBP1 to TBP4 may include a plurality of bits.

Specifically, in step S610, when the row test pattern generator 310 generates the test data TRP1 to TRP4 with the logic value of 0000 according to the control signal CSTX, and the column test pattern generator 320 generates the test data TCP1 to TCP4 with the logic value of 1111 according to the control signal CSTX, the test circuits TX11 to TX44 of the test device 300 may operate in the second test mode.

In the second test mode, the logic gates LOC1 in the test circuits TX11 to TX44 may respectively generate the detection signals DS11 to DS44 with the logic value of 0 according to the test data TRP1 to TRP4 with the logic value of 0000 and the test data TCP1 to TCP4 with the logic value of 1111 respectively. In addition, the multiplexers MUX in the test circuits TX11 to TX44 may select and transmit the detection signals DS11 to DS44 with the logic value of 0 to the corresponding connection lines P11 to P44 respectively based on the mode selection signal MODE.

On the other hand, in step S620, when the row test pattern generator 410 generates the test data TAP1 to TAP4 with the logic value of 0000 according to the control signal CSRX, and the column test pattern generator 420 generates the test data TBP1 to TBP4 with the logic value of 0000 according to the control signal CSRX, the test circuits RX11 to RX44 of the test device 300 may operate in the second test mode.

In the second test mode, the comparators COM in these test circuits RX11 to RX44 may receive the detection signals DS11 to DS44 with the logic value of 0 respectively through the corresponding connection lines P11 to P44.

For the convenience of description, the test circuit RX11 is taken as an example for description here, and the operation methods of the remaining test circuits RX12 to RX44 may be derived by analogy. For example, in this embodiment, the logic gate LOC2 of the test circuit RX11 may generate the output signal with the logic value of 1 according to the test data TAP1 with the logic value of 0 and the test data TBP1 with the logic value of 0. Then, the comparator COM of the test circuit RX11 may generate the test result C[0] with the logic value of 0 according to the output signal with the logic value of 1 and the detection signal DS11 with the logic value of 0.

It is worth mentioning that in step S630, when the test result C[0] of the test circuit RX11 is the logic value of 0, it means that in the transmission path where the test circuit TX11 transmits the detection signal DS11 to the test circuit RX11 through the connection line P11, the connection line P11 does not have the abnormal state, and the detection signal DS11 may be

### Maintained at a Logic of 0.

In this case, in the second test mode, the test device 300 may test or determine that the corresponding connection line P11 operates in the normal connection state according to the test result C[0] with the logic value of 0.

In contrast, as shown in FIG. 4B, it is assumed that when in the transmission path where the test circuit TX13 transmits the detection signal DS13 to the test circuit RX13 through the connection line P13, the connection line P13 has the abnormal state (that is, the connection line P13 and the ground voltage in the chip are in the short-circuit state), causing the logic value of the detection signal DS13 to change from the original logic value of 0 to the logic value of 1, the test circuit RX13 will generate the test result C[2] with the logic value of 1 according to the detection signal DS13, the test data TAP3, and the test data TBP3.

In this case, the test device 300 may determine that the corresponding connection line P13 operates in the abnormal connection state according to the test result C[2] with the logic value of 1 (step S630). In other words, in the second test mode, the test device 300 may test or determine that the corresponding connection line P13 and the power supply voltage in the chip are in the short-circuit state (that is, stuck-at-1) according to the test result C[2] with the logic value of 1.

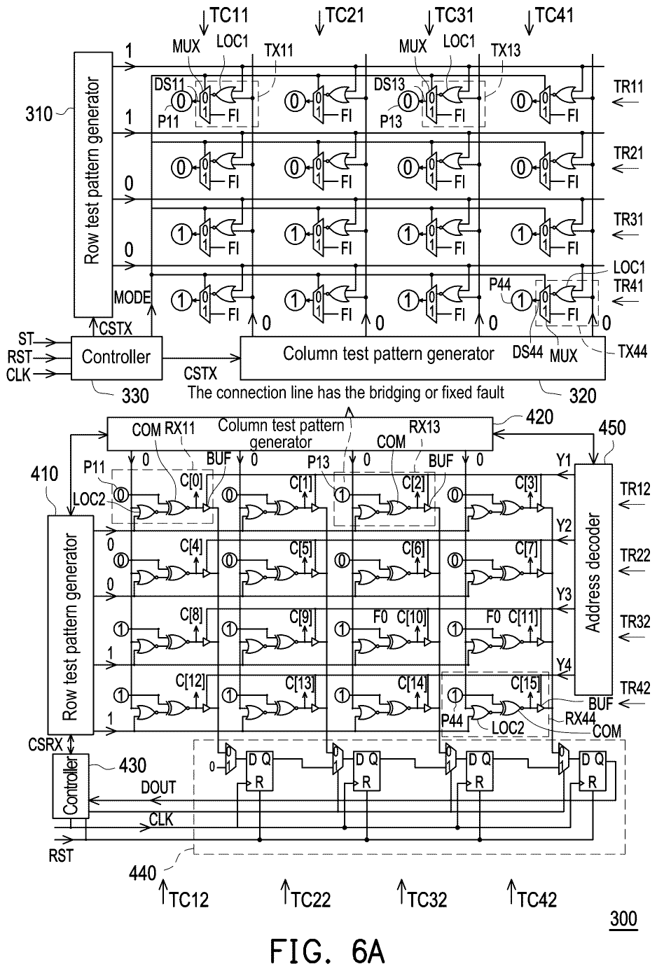

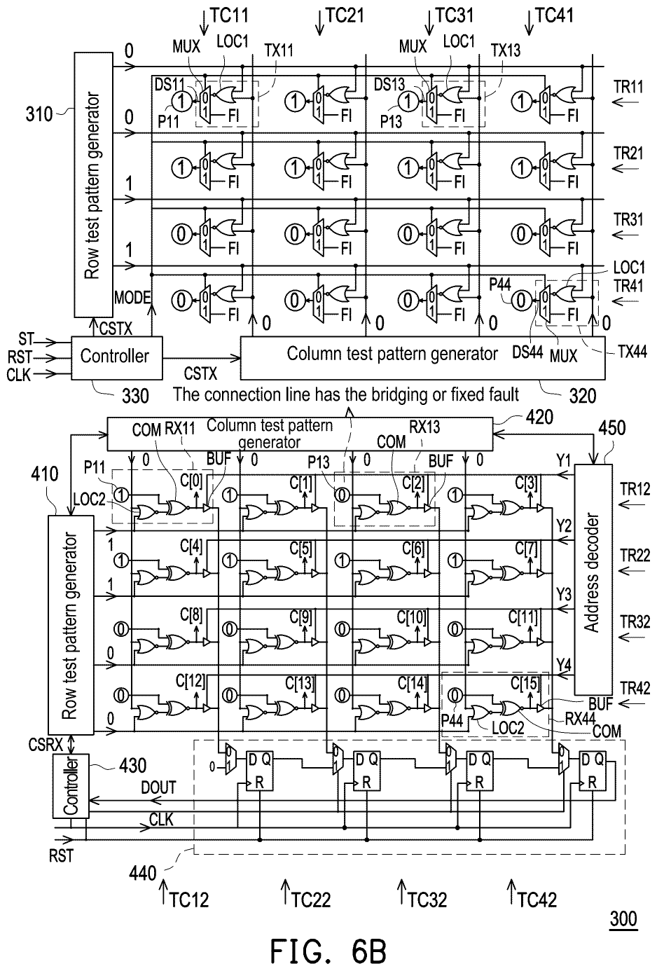

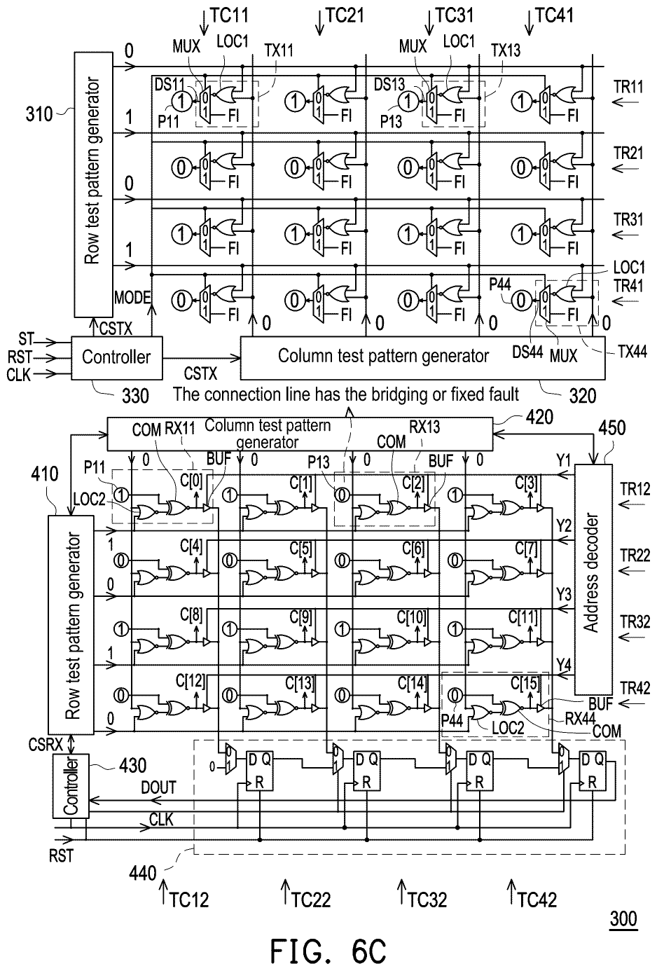

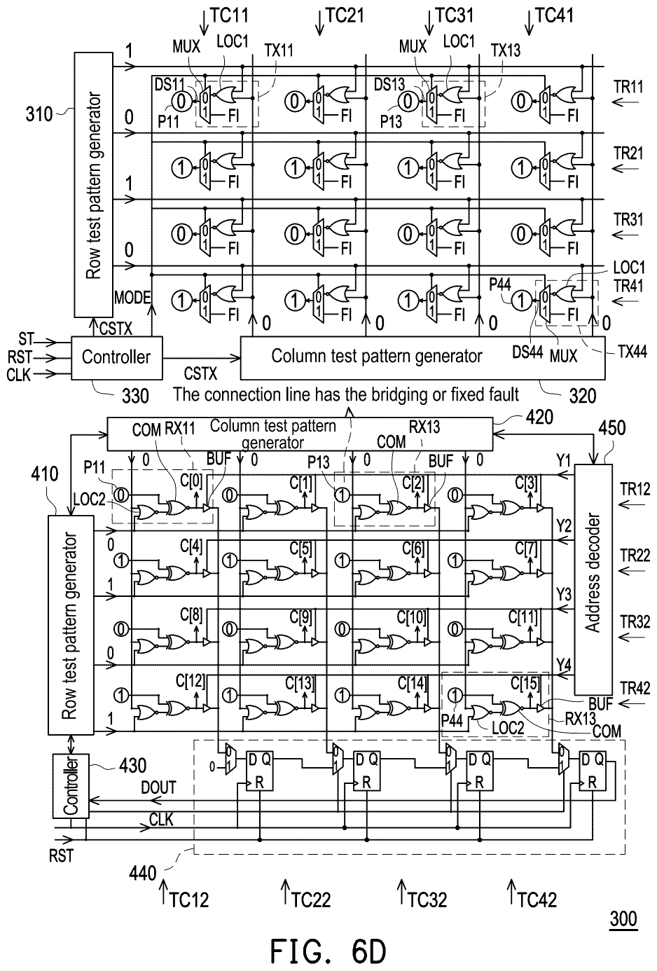

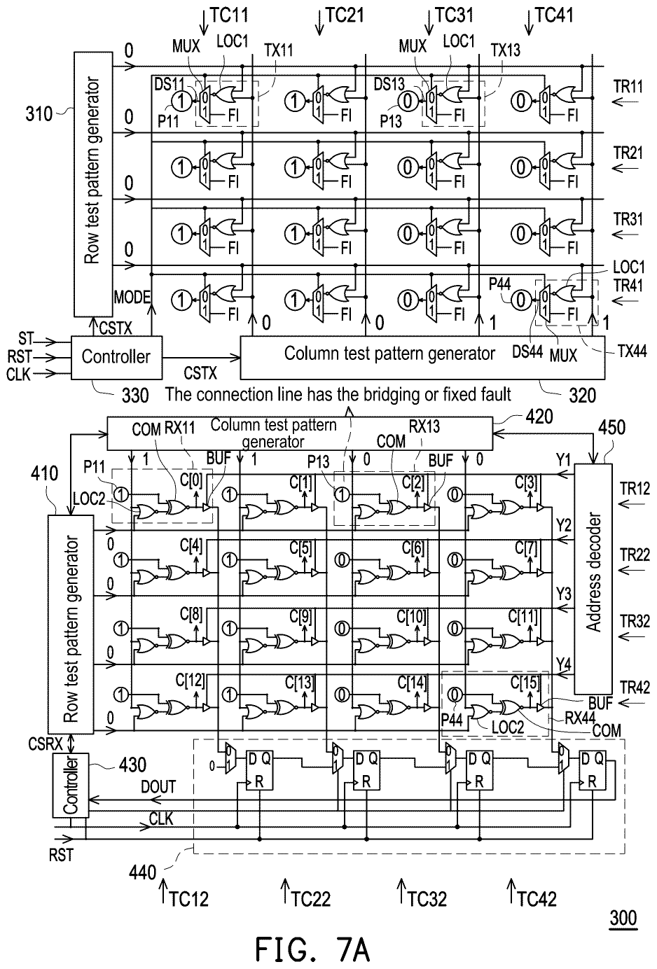

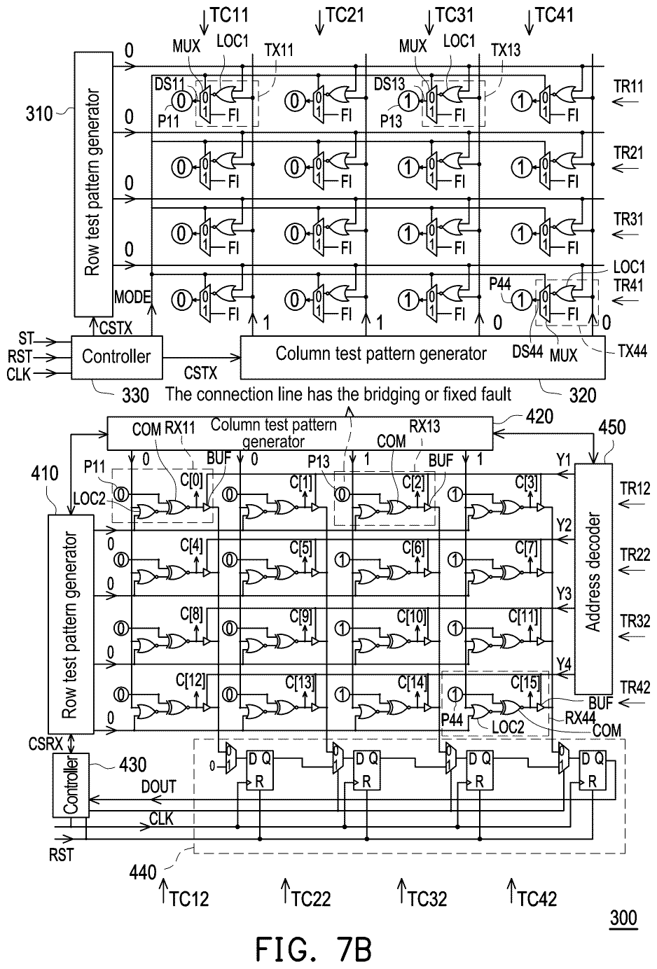

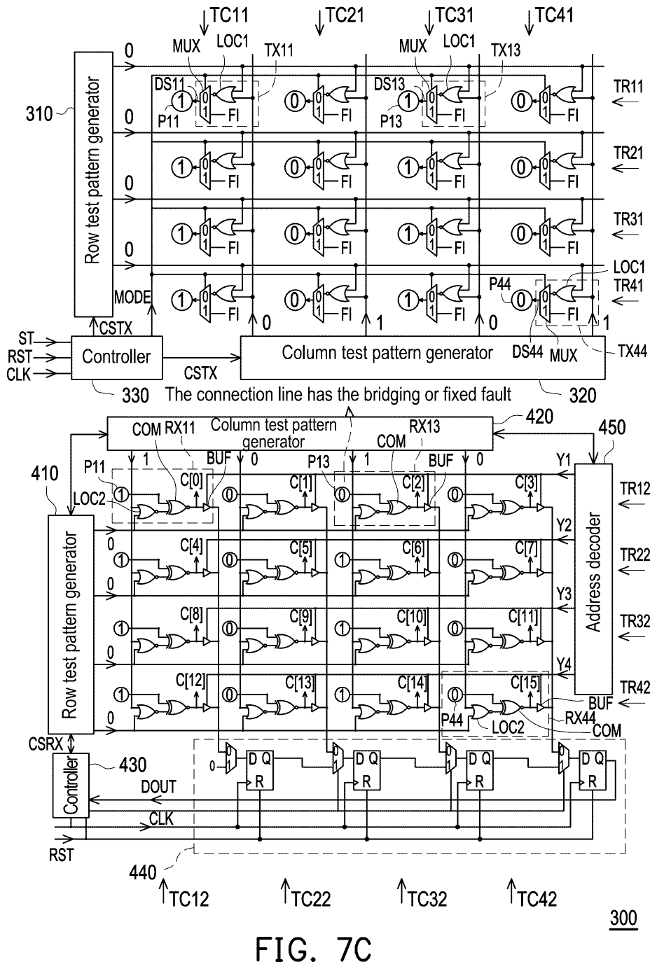

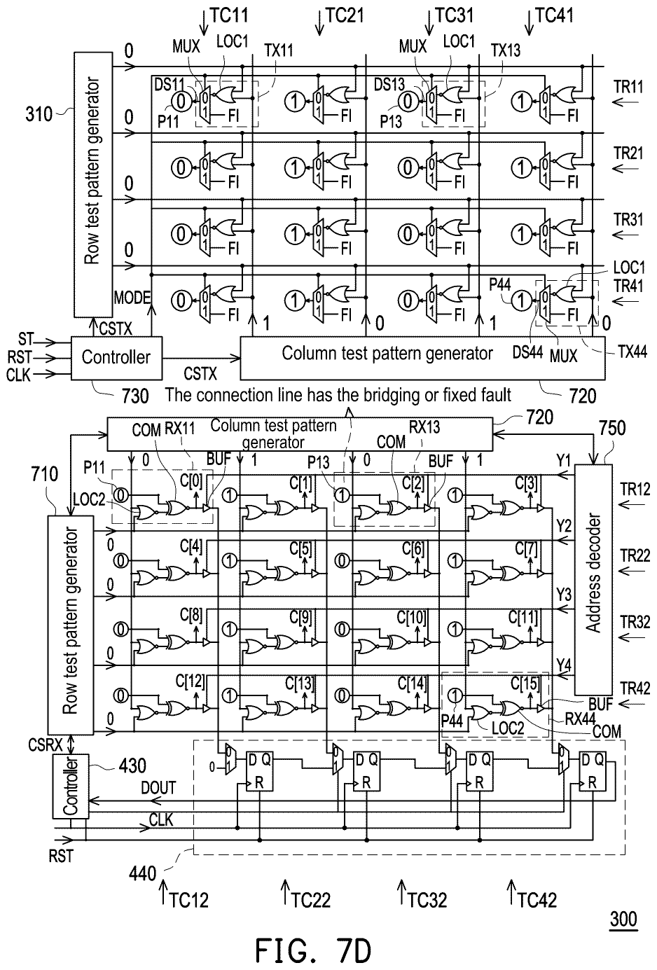

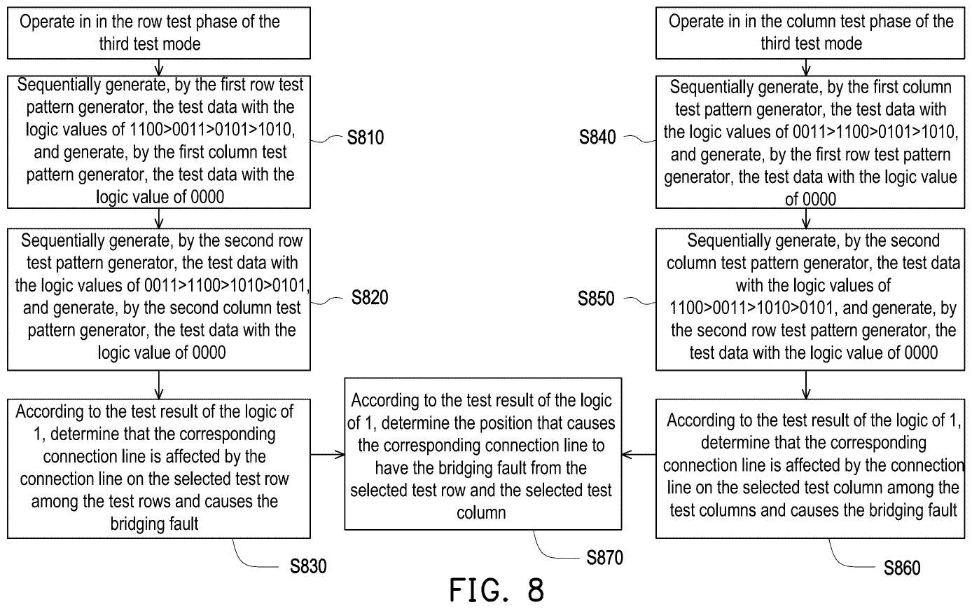

FIGS. 6A to 6D are respectively schematic diagrams of the test device 300 shown in FIG. 3 operating in a row test phase of a third test mode according to the disclosure, FIGS. 7A to 7D are respectively schematic diagrams of the test device 300 shown in FIG. 3 operating in a column test phase of the third test mode according to the disclosure, and FIG. 8 is an operation flowchart of the test device 300 in FIGS. 6A to 6D and 7A to 7D operating in the row test phase and the column test phase of the third test mode according to an embodiment and of the disclosure.

It should be noted that the test device 300 shown in FIGS. 6A to 7D is the same as or similar to the test device 300 shown in FIG. 3. FIGS. 6A to 6D show a situation state when the test circuits TX11 to TX44 and the test circuits RX11 to RX44 of the test device 300 operate in the row test phase of the third test mode, and FIGS. 7A to 7D show a situation state when the test circuits TX11 to TX44 and the test circuits RX11 to RX44 of the test device 300 operate in the column test phase of the third test mode.

When operating in the third test mode, the test device 300 may test which of the connection lines P11 to P44 has a fixed fault or a bridging fault according to the test results C[0] to C[15]. In addition, the test device 300 may also test a fault type of which of the connection lines according to the test results C[0] to C[15], such as a stuck-at-0 fault, a stuck-at-1 fault, a wired-AND bridging fault, a wired-OR bridging fault.

In addition, the test device 300 may perform operation actions of the row test phase of the third test mode according to steps S810 to S830 in FIG. 8, and the test device 300 may perform operation actions of the column test phase of the third test mode according to steps S840 to S860 in FIG. 8.

Specifically, in step S810, the row test pattern generator 310 of the test device 300 may sequentially generate the test data TRP1 of TRP4 with logic values of a plurality of first test bytes being 1100, 0011, 0101, and 1010 according to the control signal CSTX. Furthermore, the column test pattern generator 320 of the test device 300 may generate the test data TCP1 to TCP4 with the logic value of 0000 according to the control signal CSTX.

Then, in step S820, the row test pattern generator 410 of the test device 300 may sequentially generate the test data TAP1 to TAP4 with logic values of a plurality of second test bytes being 0011, 1100, 1010, and 0101 according to the control signal CSRX. Furthermore, the column test pattern generator 420 of the test device 300 may generate the test data TBP1 to TBP4 with the logic value of 0000 according to the control signal CSRX.

In this regard, referring to FIG. 6A, In a first sub-phase of the row test phase the third test mode, the row test pattern generator 310 can generate the first byte with the logic value of 1100 (i.e., the test data TRP1 to TRP4) to the test circuits TX11 to TX44, and the column test pattern generator 320 may generate the test data TCP1 to TCP4 with the logic value of 0000 to the test circuits TX11 to TX44 according to the control signal CSTX.

Then, the logic gates LOC1 in the test circuits TX11 to TX44 may respectively generate the detection signals DS11 to DS44 according to the test data TRP1 to TRP4 and the test data TCP1 to TCP4 respectively. In addition, the multiplexers MUX in the test circuits TX11 to TX44 may choose to respectively transmit the detection signals DS11 to DS44 to the corresponding connection lines P11 to P44 based on the mode selection signal MODE.

In the first sub-phase of the row test phase of the third test mode, the test circuits TX11 to TX24 on the test rows TR11 and TR21 may respectively generate the detection signals DS11 to DS24 with the logic of 0. In addition, the test circuits TX31 to TX44 on the test rows TR31 and TR41 may respectively generate the detection signals DS31 to DS44 with the logic of 1.

On the other hand, in the first sub-phase of the row test phase of the third test mode, the row test pattern generator 410 may generate the second byte with the logic value of 0011 (i.e., the test data TAP1 to TAP4) to the test circuits RX11 to RX44, and the column test pattern generator 420 may generate the test data TBP1 to TBP4 with the logic value of 0000 to the test circuits RX11 to RX44 according to the control signal CSRX.

Next, as shown in FIG. 6A, in this embodiment, it is assumed that the connection line P13 is affected by other connection lines, causing the logic value of the detection signal DS13 received by the test circuit RX13 from the connection line P13 to change from the original logic value of 0 to the logic value of 1. At this time, the test device 300 may determine that the corresponding connection line P13 is in the abnormal state (that is, the bridging fault occurs in the connection line P13) according to the test result C[2] with the logic value of 1.

Referring to FIG. 6B, in a second sub-phase of the row test phase of the third test mode, the row test pattern generator 310 may generate the first byte with the logic value of 0011 (i.e., the test data TRP1 to TRP4) to the test circuits TX11 to TX44 according to the control signal CSTX, and the column test pattern generator 320 may generate the test data TCP1 to TCP4 with the logic value of 0000 to the test circuits TX11 to TX44 according to the control signal CSTX.

In this case, the test circuits TX11 to TX24 on the test rows TR11 and TR21 may respectively generate the detection signals DS11 to DS 24 with the logic of 1. Furthermore, the test circuits TX31 to TX44 on the test rows TR31 and TR41 may respectively generate the detection signals DS31 to DS44 with the logic of 0.

On the other hand, in the second sub-phase of the row test phase of the third test mode, the row test pattern generator 410 may generate the second byte with the logic value of 1100 (i.e., the test data TAP1 to TAP4) to the test circuits RX11 to RX44, and the column test pattern generator 420 may generate the test data TBP1 to TBP4 with the logic value of 0000 to the test circuits RX11 to RX44 according to the control signal CSRX.

When the abnormal state occurs in the connection line P13, the logic value of the detection signal DS13 received by the test circuit RX13 from the connection line P13 changes from the original logic value of 1 to the logic value of 0. At this time, the test circuit RX13 may generate the test result C[2] with the logic value of 1 according to the detection signal DS13 with the logic value of 0.

It should be noted here that according to the embodiment of FIG. 6A, it may be known that the detection signal DS13 on the connection line P13 is mainly interfered by the detection signals DS31 to DS44 with the logic value of 1 on the connection lines P31 to P44 of the test rows TR32 and TR42 (or TR31 and TR41), causing the detection signal DS13 on the connection line P13 to change from the original logic of 0 to the logic of 1. In addition, according to the embodiment of FIG. 6B, it may be known that the detection signal DS13 on the connection line P13 is mainly interfered by the detection signals DS31 to DS44 with the logic value of 0 on the connection lines P31 to P44 of the test rows TR32 and TR42 (or TR31 and TR41), causing the detection signal DS13 on the connection line P13 to change from the original logic of 1 to the logic of 0.

Therefore, the test device 300 may determine that the connection line P13 is affected by one of the connection lines P31 to P44 on the test rows TR32 and TR42 (or TR31 and TR41) among the test rows of the test device 300 and causes the bridging fault (step S830) according to a change state of the detection signal DS13 and the test result C[2] based on adjustment of the first byte (or the test data TRP1 to TRP4) and the second byte (or the test data TAP1 to TAP4).

Referring to FIG. 6C, in a third sub-phase of the row test phase of the third test mode, the row test pattern generator 310 may generate the first byte with the logic value of 0101 (i.e., the test data TRP1 to TRP4) to the test circuits TX11 to TX44 according to the control signal CSTX, and the column test pattern generator 320 may generate the test data TCP1 to TCP4 with the logic value of 0000 to the test circuits TX11 to TX44 according to the control signal CSTX.

In this case, the test circuits TX11 to TX14 and T31 to T34 on the test rows TR11 and TR31 may respectively generate the detection signals DS11 to DS14 and DS31 to DS34 with the logic of 1. In addition, the test circuits TX21 to TX 24 and TX41 to TX44 on the test rows TR21 and TR41 may respectively generate the detection signals DS21 to DS24 and DS41 to DS44 with the logic of 0.

On the other hand, in the third sub-phase of the row test phase of the third test mode, the row test pattern generator 410 may generate the second byte with the logic value of 1010 (i.e., the test data TAP1 to TAP4) to the test circuits RX11 to RX44, and the column test pattern generator 420 may generate the test data TBP1 to TBP4 with the logic value of 0000 to the test circuits RX11 to RX44 according to the control signal CSRX.

When the abnormal state occurs in the connection line P13, the logic value of the detection signal DS13 received by the test circuit RX13 from the connection line P13 changes from the original logic value of 1 to the logic value of 0. At this time, the test circuit RX13 may generate the test result C[2] with the logic value of 1 according to the detection signal DS13 with the logic value of 0.

Referring to FIG. 6D, in a fourth sub-phase of the row test phase of the third test mode, the row test pattern generator 310 may generate the first byte with the logic value of 1010 (i.e., the test data TRP1 to TRP4) to the test circuits TX11 to TX44 according to the control signal CSTX, and the column test pattern generator 320 may generate the test data TCP1 to TCP4 with the logic value of 0000 to the test circuits TX11 to TX44 according to the control signal CSTX.

In this case, the test circuits TX11 to TX14 and T31 to T34 on the test rows TR11 and TR31 may respectively generate the detection signals DS11 to DS14 and DS31 to DS34 with the logic of 0. In addition, the test circuits TX21 to TX 24 and TX41 to TX44 on the test rows TR21 and TR41 may respectively generate the detection signals DS21 to DS24 and DS41 to DS44 with the logic of 1.

On the other hand, in the fourth sub-phase of the row test phase of the third test mode, row test pattern generator 410 may generate the second byte with the logic value of 0101 (i.e., the test data TAP1 to TAP4) to the test circuits RX11 to RX44, and the column test pattern generator 420 may generate the test data TBP1 to TBP4 with the logic value of 0000 to the test circuits RX11 to RX44 according to the control signal CSRX.

When the abnormal state occurs in the connection line P13, the logic value of the detection signal DS13 received by the test circuit RX13 from the connection line P13 changes from the original logic value of 0 to the logic value of 1. At this time, the test circuit RX13 may generate the test result C[2] with the logic value of 1 according to the detection signal DS13 with the logic value of 1.

It should be noted that according to the embodiment of FIG. 6C, it may be known that the detection signal DS13 on the connection line P13 is mainly interfered by the detection signals DS41 to DS44 with the logic value of 0 on the connection lines P41 to P44 of the test row TR42 (or TR41), causing the detection signal DS13 on the connection line P13 to change from the original logic of 1 to the logic of 0. In addition, according to the embodiment of FIG. 6D, it may be known that the detection signal DS13 on the connection line P13 is mainly interfered by the detection signals DS41 to DS44 with the logic value of 1 on the connection lines P41˜P44 of the test row TR42 (or TR41), causing the detection signal DS13 on the connection line P13 to change from the original logic of 0 to the logic of 1.

Therefore, the test device 300 may determine that the connection line P13 is affected by one of the connection lines P41 to P44 on the test rows TR42 (or TR41) among the test rows of the test device 300 and causes the bridging fault (step S830) according to the change state of the detection signal DS13 and the test result C[2] based on the adjustment of the first byte (or the test data TRP1 to TRP4) and the second byte (or the test data TAP1 to TAP4).

Thus, according to the above exemplary descriptions of FIGS. 6A to 6D (steps S810 to S830), the test device 300 in this embodiment may determine that the corresponding connection line P13 is an abnormal connection line according to the test result C[2]. In addition, the test device 300 may determine that the connection line P13 will be affected by one of the connection lines P41 to P44 on the test row TR42 (or TR41) and cause the bridging fault (step S830) according to the change state of the detection signal DS13 and the test result C[2], so as to select the test row TR42 (or TR41) as the selected test row.

Returning to FIG. 8 here, in step S840, the column test pattern generator 320 of the test device 300 may sequentially generate the test data TCP1 to TCP4 with the logic values of the first test bytes being 0011, 1100, 0101, and 1010 according to the control signal CSTX. In addition, the row test pattern generator 310 of the test device 300 may generate the test data TRP1 to TRP4 with the logic value of 0000 according to the control signal CSTX.

Next, in step S850, the column test pattern generator 420 of the test device 300 may sequentially generate the test data TBP1 to TBP4 with the logic values of the second test bytes being 1100, 0011, 1010, and 0101 according to the control signal CSRX. In addition, the row test pattern generator 410 of the test device 300 may generate the test data TAP1 to TAP4 with the logic value of 0000 according to the control signal CSRX.

In this regard, referring to FIG. 7A, in a first sub-phase of the column test phase of the third test mode, the column test pattern generator 320 may generate the first byte with the logic value of 0011 (i.e., the test data TCP1 to TCP4) to the test circuits TX11 to TX44 according to the control signal CSTX, and the row test pattern generator 310 may generate the test data TRP1 to TRP4 with the logic value of 0000 to the test circuits TX11 to TX44 according to the control signal CSTX.

Then, the logic gates LOC1 in the test circuits TX11 to TX44 may respectively generate the detection signals DS11 to DS44 according to the test data TRP1 to TRP4 and the test data TCP1 to TCP4 respectively. In addition, the multiplexers MUX in the test circuits TX11 to TX44 may choose to respectively transmit the detection signals DS11 to DS44 to the corresponding connection lines P11 to P44 based on the mode selection signal MODE.

In the first sub-phase of the column test phase of the third test mode, the test circuits on the test columns TC11 and TC21 may respectively generate the detection signals with the logic of 1. In addition, the test circuits on the test columns TC31 and TC41 may respectively generate the detection signals with the logic of 0.

On the other hand, in the first sub-phase of the column test phase of the third test mode, the column test pattern generator 420 may generate the second byte with the logic value of 1100 (i.e., the test data TBP1 to TBP4) to the test circuits RX11 to RX44 according to the control signal CSRX, and the row test pattern generator 410 may generate the test data TAP1 to TAP4 with the logic value of 0000 to the test circuits RX11 to RX44 according to the control signal CSRX.

Next, as shown in FIG. 7A, in this embodiment, it is assumed that the connection line P13 is affected by other connection lines, causing the logic value of the detection signal DS13 received by the test circuit RX13 from the connection line P13 to change from the original logic value of 0 to the logic value of 1. At this time, the test device 300 may determine that the corresponding connection line P13 is in the abnormal state (that is, the bridging fault occurs in the connection line P13) according to the test result C[2] with the logic value of 1.

Referring to FIG. 7B, in a second sub-phase of the column test phase of the third test mode, the column test pattern generator 320 may generate the first byte with the logic value of 1100 (i.e., the test data TCP1 to TCP4) to the test circuits TX11 to TX44 according to the control signal CSTX, and the row test pattern generator 310 may generate the test data TRP1 to TRP4 with the logic value of 0000 to the test circuits TX11 to TX44 according to the control signal CSTX.

In this case, the test circuits on the test columns TC11 and TC21 may respectively generate the detection signals with the logic of 0. In addition, the test circuits on the test columns TC31 and TC41 may respectively generate the detection signals with the logic of 1.

On the other hand, in the second sub-phase of the column test phase of the third test mode, the column test pattern generator 420 may generate the second byte with the logic value of 0011 (i.e., the test data TBP1 to TBP4) to the test circuits RX11 to RX44 according to the control signal CSRX, and the row test pattern generator 410 may generate the test data TAP1 to TAP4 with the logic value of 0000 to the test circuits RX11 to RX44 according to the control signal CSRX.

When the abnormal state occurs in the connection line P13, the logic value of the detection signal DS13 received by the test circuit RX13 from the connection line P13 changes from the original logic value of 1 to the logic value of 0. At this time, the test circuit RX13 may generate the test result C[2] with the logic value of 1 according to the detection signal DS13 with the logic value of 0.

It should be noted here that according to the embodiment of FIG. 7A, it may be known that the detection signal DS13 on the connection line P13 is mainly interfered by the detection signals with the logic value of 1 on the connection lines of the test columns TC12 and TC22 (or TC11 and TC21), causing the detection signal DS13 on the connection line P13 to change from the original logic of 0 to the logic of 1. In addition, according to the embodiment of FIG. 7B, it may be known that the detection signal DS13 on the connection line P13 is mainly interfered by the detection signals with the logic value of 0 on the connection lines of the test columns TC12 and TC22 (or TC11 and TC21), causing the detection signal DS13 on the connection line P13 to change from the original logic of 1 to the logic of 0.

Therefore, the test device 300 may determine that the connection line P13 will be affected by one of the connection lines on the test columns TC12 and TC22 (or TC11 and TC21) among the test columns of the test device 300 and causes the bridging fault (step S860) according to the change state of the detection signal DS13 and the test result C[2] based on the adjustment of the first byte (or the test data TCP1 to TCP4) and the second byte (or the test data TBP1 to TBP4).

Referring to FIG. 7C, in a third sub-phase of the column test phase of the third test mode, the column test pattern generator 320 may generate the first byte with the logic value of 0101 (i.e., the test data TCP1 to TCP4) to the test circuits TX11 to TX44 according to the control signal CSTX, and the row test pattern generator 310 may generate the test data TRP1 to TRP4 with the logic value of 0000 to the test circuits TX11 to TX44 according to the control signal CSTX.

In this case, the test circuits on the test columns TC11 and TC31 may respectively generate the detection signals with the logic of 1. In addition, the test circuits on the test columns TC21 and TC41 may respectively generate the detection signals with the logic of 0.

On the other hand, in the third sub-phase of the column test phase of the third test mode, the column test pattern generator 420 may generate the second byte with the logic value of 1010 (i.e., the test data TBP1 to TBP4) to the test circuits RX11 to RX44 according to the control signal CSRX, and the row test pattern generator 410 may generate the test data TAP1 to TAP4 with the logic value of 0000 to the test circuits RX11 to RX44 according to the control signal CSRX.

When the abnormal state occurs in the connection line P13, the logic value of the detection signal DS13 received by the test circuit RX13 from the connection line P13 changes from the original logic value of 1 to the logic value of 0. At this time, the test circuit RX13 may generate the test result C[2] with the logic value of 1 according to the detection signal DS13 with the logic value of 0.

Referring to FIG. 7D, in a fourth sub-phase of the column test phase of the third test mode, the column test pattern generator 320 may generate the first byte with the logic value of 1010 (i.e., the test data TCP1 to TCP4) to the test circuits TX11 to TX44 according to the control signal CSTX, and the row test pattern generator 310 may generate the test data TRP1 to TRP4 with the logic value of 0000 to the test circuits TX11 to TX44 according to the control signal CSTX.

In this case, the test circuits on the test columns TC11 and TC31 may respectively generate the detection signals with the logic of 0. In addition, the test circuits on the test columns TC21 and TC41 may respectively generate the detection signals with the logic of 1.

On the other hand, in the fourth sub-phase of the column test phase of the third test mode, the column test pattern generator 420 may generate the second byte with the logic value of 0101 (i.e., the test data TBP1 to TBP4) to the test circuits RX11 to RX44 according to the control signal CSRX, and the row test pattern generator 410 may generate the test data TAP1 to TAP4 with the logic value of 0000 to the test circuits RX11 to RX44 according to the control signal CSRX.

When the abnormal state occurs in the connection line P13, the logic value of the detection signal DS13 received by the test circuit RX13 from the connection line P13 changes from the original logic value of 0 to the logic value of 1. At this time, the test circuit RX13 may generate the test result C[2] with the logic value of 1 according to the detection signal DS13 with the logic value of 1.

It should be noted here that according to the embodiment of FIG. 7C, it may be known that the detection signal DS13 on the connection line P13 is mainly interfered by the detection signals with the logic value of 0 on the connection lines of the test column TC22 (or TC21), causing the detection signal DS13 on the connection line P13 to change from the original logic of 1 to the logic of 0. In addition, according to the embodiment of FIG. 7D, it may be known that the detection signal DS13 on the connection line P13 is mainly interfered by the detection signals with the logic value of 1 on the connection lines of the test column TC22 (or TC21), causing the detection signal DS13 on the connection line P13 to change from the original logic of 0 to the logic of 1.

Therefore, the test device 300 may determine that the connection line P13 will be affected by one of the connection lines on the test column TC22 (or TC21) among the test columns of the test device 300 and causes the bridging fault (step S860) according to the change state of the detection signal DS13 and the test result C[2] based on the adjustment of the first byte (or the test data TCP1 to TCP4) and the second byte (or the test data TBP1 to TBP4).

Thus, according to the above exemplary descriptions of FIGS. 7A to 7D (steps S840 to S860), the test device 300 in this embodiment may determine that the corresponding connection line P13 is an abnormal connection line according to the test result C[2]. In addition, the test device 300 may determine that the connection line P13 will be affected by one of the connection lines on the test column TC22 (or TC21) and cause the bridging fault (step S860) according to the change state of the detection signal DS13 and the test result C[2], so as to select the test column TC22 (or TC21) as the selected test column.

According to the relevant descriptions of FIGS. 6A to 7D, in step S870, the test device 300 may determine that, from the selected test row TR42 (or TR41) and the selected test column TC22 (or TC21) based on the test result C[2] with the logic of 1, the connection line causing the bridging fault of the corresponding connection line P13 is the connection line P42 located at the selected test row TR42 (or TR41) and the selected test column TC22 (or TC21).

In addition, returning to FIG. 3, in other embodiments, the test device 300 may enable the test circuit array AR1 to have a plurality of first test partitions and the test circuit array AR2 to have a plurality of second test partitions according to design requirements. Thus, the test device 300 may test the connection line in the abnormal state for each of the test partitions according to the relevant descriptions mentioned in FIGS. 1 to 8.

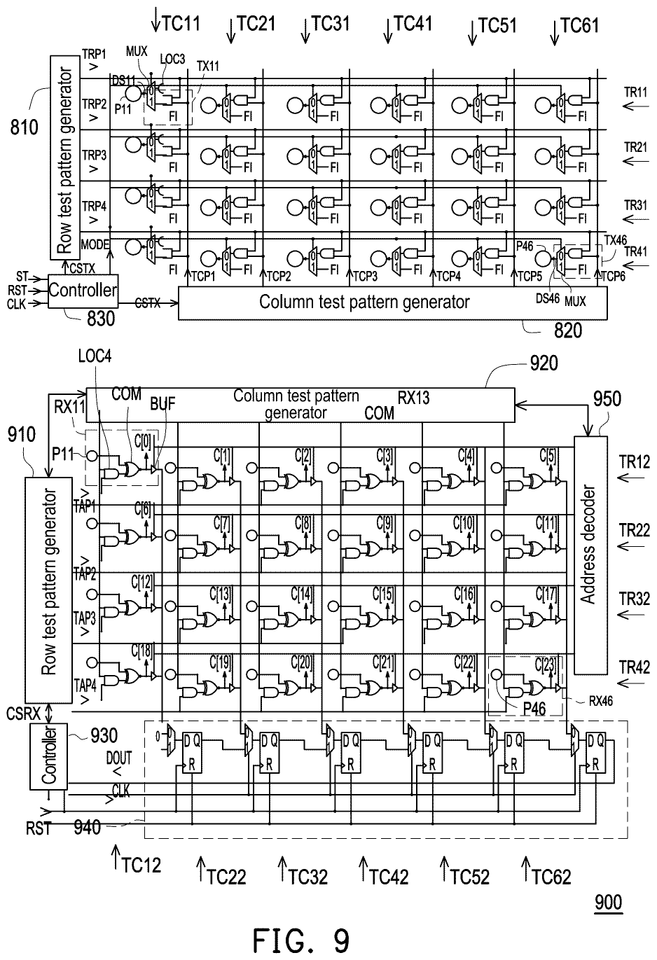

FIG. 9 is a circuit diagram of a test device according to another embodiment of FIG. 2 of the disclosure. Referring to FIGS. 2, 3, and 9 together, in this embodiment, a test device 900 includes a plurality of connection lines P11 to P46, a plurality of test circuits TX11 to TX46, a row test pattern generator 810, and a column test pattern generator 820, and a controller 830. The test circuits TX11 to TX46 (that is, the first test circuits) may be arranged in a 4*6 matrix.

In particular, operating functions and coupling methods of the test circuits TX11 to TX46, the row test pattern generator 810, the column test pattern generator 820, and the controller 830 shown in FIG. 9 are respectively the same as or similar to the operating functions and coupling methods of the test circuits TX11 to TXNM, the row test pattern generator 110, the column test pattern generator 120, and the controller 130 shown in FIG. 2. Therefore, the test circuits TX11 to TX46, the row test pattern generator 810, the column test pattern generator 820, and the controller 830 shown in FIG. 9 may be derived by analogy with reference to the related descriptions of the test circuits TX11 to TXNM, the row test pattern generator 110, the column test pattern generator 120, and the controller 130 mentioned in FIG. 2. Therefore, the same details will not be repeated in the following. In addition, in FIGS. 2, 3, and 9, the same or similar elements or components will be denoted by the same or similar reference numerals.

Different from the embodiment of FIG. 3, in the test device 900 shown in FIG. 9, each of the test circuits TX11 to TX46 may include a logic gate LOC3 and the multiplexer MUX. In the embodiment of FIG. 9, the logic gate LOC3 may be implemented by an AND gate.

On the other hand, in the embodiment of FIG. 9, the test device 900 further includes a plurality of test circuits RX11 to RX46 (i.e., the second test circuits), a row test pattern generator 910, a column test pattern generator 920, a controller 930, a shift register 940, and an address decoder 950.

In particular, operating functions and coupling methods of the test circuits RX11 to RX46, the row test pattern generator 910, the column test pattern generator 920, the controller 930, the shift register 940, and the address decoder 950 shown in FIG. 9 are respectively the same as or similar to the operating functions and coupling methods of the test circuits RX11 to RXNM, the row test pattern generator 210, the column test pattern generator 220, the controller 230, the shift register 240, and the address decoder 250 shown in FIG. 2. Therefore, the test circuits RX11 to RX46, the row test pattern generator 910, the column test pattern generator 920, the controller 930, the shift register 940, and the address decoder 950 shown in FIG. 9 may be derived by analogy with reference to the related descriptions of the test circuits RX11 to RXNM, the row test pattern generator 210, the column test pattern generator 220, the controller 230, the shift register 240, and the address decoder 250 mentioned in FIG. 2. Therefore, the same details will not be repeated in the following. In addition, in FIGS. 2, 3, and 9, the same or similar elements or components will be denoted by the same or similar reference numerals.

Different from the embodiment of FIG. 3, in the test device 900 shown in FIG. 9, each of the test circuits RX11 to RX46 may include a logic gate LOC4, the comparator COM, and the buffer BUF. In the embodiment of FIG. 9, the logic gate LOC4 may be implemented by the AND gate, and the comparator COM may be implemented by the XNOR gate.

It is worth mentioning that for implementation of the test device 900 operating in the first test mode and the second test mode, reference may be made to relevant descriptions of the test device 300 operating in the first test mode and the second test mode mentioned in FIGS. 3 to 5 and derived by analogy. Therefore, the same details will not be repeated in the following.

It should be noted that in the embodiment shown in FIG. 9, when the test device 900 operates in the row test phase of the third test mode, the row test pattern generator 810 of the test device 900 may sequentially generate the test data TRP1 to TRP4 with the logic values of the first test bytes being 1100, 0011, 0101, and 1010 according to the control signal CSTX. In addition, the column test pattern generator 820 of the test device 900 may generate the test data TCP1 to TCP6 with a logic value of 111111 according to the control signal CSTX.

In addition, when the test device 900 operates in the row test phase of the third test mode, the row test pattern generator 910 of the test device 900 may sequentially generate the test data TAP1 to TAP4 with the logic values of the second test bytes being 1100, 0011, 0101, and 1010 according to the control signal CSRX. In addition, the column test pattern generator 920 of the test device 900 may generate the test data TBP1 to TBP 6 with the logic value of 111111 according to the control signal CSRX.

On the other hand, when the test device 900 operates in the column test phase of the third test mode, the column test pattern generator 820 of the test device 900 may sequentially generate the test data TCP1 to TCP6 with the logic values of the first test bytes being 000011, 111100, 001100, 110011, 010101, and 101010 according to the control signal CSTX. In addition, the row test pattern generator 810 of the test device 900 may generate the test data TRP1 to TRP4 with the logic value of 111111 according to the control signal CSTX.

In addition, when the test device 900 operates in the column test phase of the third test mode, the column test pattern generator 920 of the test device 900 may sequentially generate the test data TBP1 to TBP6 with the logic values of the second test bytes being 000011, 111100, 001100, 110011, 010101, and 101010 according to the control signal CSRX. In addition, the row test pattern generator 910 of the test device 900 may generate the test data TAP1 to TBP4 with the logic value of 1111 according to the control signal CSRX.

For implementation of the test device 900 operating in the third test mode, reference may be made to the relevant descriptions of the test device 300 operating in the third test mode mentioned in FIGS. 3 and 6A to 8 and derived by analogy. Therefore, the same details will not be repeated in the following.

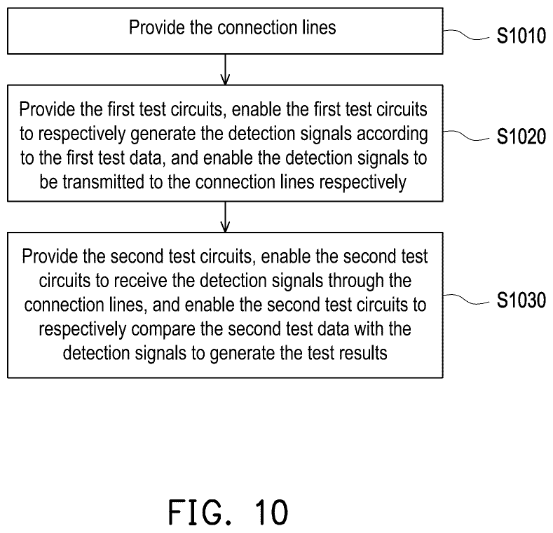

FIG. 10 is a flowchart of a test method of a test device according to an embodiment of the disclosure. In step S1010, the test device provides the connection lines. In step S1020, the test device provides the first test circuits, enables the first test circuits to respectively generate the detection signals according to the first test data, and enables the detection signals to be transmitted to the connection lines respectively. In step S1030, the test device provides the second test circuits, enables the second test circuits to receive the detection signals through the connection lines, and enables the second test circuits to respectively compare the second test data with the detection signals to generate the test results.

Implementation details of the above steps have been described in detail in the foregoing embodiments. Therefore, the same details will not be repeated in the following.

Based on the above, in the test device and the test method thereof according to the embodiments of the disclosure, the test device may test which of the connection lines is in the short-circuit state with the ground voltage or the power supply voltage in the chip according to the test results in the first test mode or the second test mode. In addition, the test device may test which of the connection lines has the fixed or bridging fault according to the test results in the third test mode, and further observe test output results to determine whether the connection line has the stuck-at-0 fault, the stuck-at-1 fault, the wired-AND bridging fault, the wired-OR bridging fault. In this way, the test device in the disclosure may effectively detect the abnormal connection lines between the chips, thereby improving the operating quality of the chip.

What is claimed is:

1. A test device, comprising:
a plurality of connection lines;
a plurality of first test circuits respectively coupled to the connection lines, wherein the first test circuits respectively generate a plurality of detection signals according to a plurality of first test data, and respectively transmit the detection signals to the connection lines; and
a plurality of second test circuits respectively coupled to the connection lines, and receiving the detection signals through the connection lines, wherein the second test circuits respectively compare a plurality of second test data with the detection signals to generate a plurality of test results,
wherein the first test circuits and the second test circuits are arranged in an N*M matrix, and N and M are positive integers.

2. The test device according to claim 1, wherein the first test circuits are configured as a first test circuit array, and the second test circuits are configured as a second test circuit array, wherein the first test circuit array has a plurality of first test rows and a plurality of first test columns, and the second test circuit array has a plurality of second test rows and a plurality of second test columns.

3. The test device according to claim 2, further comprising:
a first row test pattern generator coupled to the first test circuits to generate a plurality of first row test data in the first test data to the first test circuits according to a first control signal;
a first column test pattern generator coupled to the first test circuits to generate a plurality of first column test data in the first test data to the first test circuits according to the first control signal;
a second row test pattern generator coupled to the second test circuits to generate a plurality of second row test data in the second test data to the second test circuits according to a second control signal; and
a second column test pattern generator coupled to the second test circuits to generate a plurality of second column test data in the second test data to the second test circuits according to the second control signal.

4. The test device according to claim 1, further comprising:
a shift register coupled to the second test circuits to output the test results sequentially according to a clock signal.

5. The test device according to claim 1, wherein each of the first test circuits comprises:
a logic gate used to receive the first test data and perform logic computation on the first test data to generate each of the detection signals; and
a multiplexer coupled to the logic gate to select and transmit each of the detection signals to each of the connection lines according to a mode selection signal.

6. The test device according to claim 1, wherein each of the second test circuits comprises:
a logic gate receiving the second test data and perform logic computation on the second test data to generate an output signal; and
a comparator receiving the output signal and each of the detection signals, and comparing the output signal with each of the detection signals to generate each of the test results.

7. The test device according to claim 1, wherein in a first test mode or a second test mode, when each of the test results has a first logic value, it means that the connection line corresponding to each of the test results having the first logic value operates in a normal connection state, and when each of the test results has a second logic value, it means that the connection line corresponding to each of the test results having the second logic value operates in an abnormal connection state, wherein the first logic value is different from the second logic value.

8. The test device according to claim 7, wherein the abnormal connection state comprises a short-circuit state between the connection line and a power supply voltage or a short-circuit state between the connection line and a ground voltage.

9. The test device according to claim 3, wherein in a row test phase of a third test mode, the first row test data have a plurality of first test bytes, and the second row test data have a plurality of second test bytes, wherein the first row test pattern generator sequentially generates the first test bytes to the first test circuits according to the first control signal, and the second row test pattern generator sequentially generates the first test bytes to the second test circuits according to the second control signal.

10. The test device according to claim 9, wherein in a column test phase of the third test mode, the first column test data have a plurality of third test bytes, and the second column test data have a plurality of fourth test bytes, wherein the first column test pattern generator sequentially generates the third test bytes to the first test circuits based on the first control signal, and the second column test pattern generator sequentially generates the fourth test bytes to the second test circuits according to the second control signal.

11. The test device according to claim 2, wherein the first test circuit array has a plurality of first test partitions, the second test circuit array has a plurality of second test partitions, and the second test circuits respectively test that at least one test partition of the second test partitions has a connection line operating in an abnormal connection state according to the test results.

12. A test method of a test device, comprising:
providing a plurality of connection lines;
providing a plurality of first test circuits, respectively generating, by the first test circuits, a plurality of detection signals according to a plurality of first test data, and respectively transmitting the detection signals to the connection lines; and
providing a plurality of second test circuits, receiving, by the second test circuits, the detection signals through the connection lines, and respectively comparing, by the second test circuits, a plurality of second test data with the detection signals to generate a plurality of test results,
wherein the first test circuits and the second test circuits are arranged in an N*M matrix, and N and M are positive integers.

13. The test method according to claim 12, further comprising:
configuring the first test circuits as a first test circuit array;
configuring the second test circuits as a second test circuit array;
enabling the first test circuit array to have a plurality of first test rows and a plurality of first test columns; and
enabling the second test circuit array to have a plurality of second test rows and a plurality of second test columns.

14. The test method according to claim 13, further comprising:
providing a first row test pattern generator, and generate, by the first row test pattern generator, a plurality of first row test data in the first test data to the first test circuits according to a first control signal;
providing a first column test pattern generator, and generate, by the first column test pattern generator, a plurality of first column test data in the first test data to the first test circuits according to the first control signal;
providing a second row test pattern generator, and generate, by the second row test pattern generator, a plurality of second row test data in the second test data to the second test circuits according to a second control signal; and
providing a second column test pattern generator, and generate, by the second column test pattern generator, a plurality of second column test data in the second test data to the second test circuits according to the second control signal.

15. The test method according to claim 12, further comprising:
providing a shift register, and sequentially output, by the shift register, the test results according to a clock signal.

16. The test method according to claim 12, wherein a step of providing the first test circuits, respectively generating, by the first test circuits, the detection signals according to the first test data, and respectively transmitting the detection signals to the connection lines comprises:
providing a logic gate, receiving, by the logic gate, the first test data, and performing logic computation on the first test data to generate each of the detection signals; and
providing a multiplexer, and selecting and transmitting, by the multiplexer, each of the detection signals to each of the connection lines according to a mode selection signal.

17. The test method according to claim 12, wherein a step of providing the second test circuits, receiving, by the second test circuits, the detection signals through the connection lines, and respectively comparing, by the second test circuits, the second test data with the detection signals to generate the test results comprises:
providing a logic gate, receiving, by the logic gate, the second test data, and performing logic computation on the second test data to generate an output signal; and
providing a comparator, receiving, by the comparator, the output signal and each of the detection signals, and comparing the output signal with each of the detection signals to generate each of the test results.

18. The test method according to claim 12, wherein in a first test mode or a second test mode, when each of the test results has a first logic value, it means that the connection line corresponding to each of the test results having the first logic value operates in a normal connection state, and when each of the test results has a second logic value, it means that the connection line corresponding to each of the test results having the second logic value operates in an abnormal connection state, wherein the first logic value is different from the second logic value.

19. The test method according to claim 18, wherein the abnormal connection state comprises a short-circuit state between the connection line and a power supply voltage or a short-circuit state between the connection line and a ground voltage.

20. The test method according to claim 14, wherein in a row test phase of a third test mode, the first row test data have a plurality of first test bytes, and the second row test data have a plurality of second test bytes, and the test method further comprises:
sequentially generating, by the first row test pattern generator, the first test bytes to the first test circuits according to the first control signal; and
sequentially generating, by the second row test pattern generator, the first test bytes to the second test circuits according to the second control signal.

21. The test method according to claim 20, wherein in a column test phase of the third test mode, the first column test data have a plurality of third test bytes, and the second column test data have a plurality of fourth test bytes, and the test method further comprises:
sequentially generating, by the first column test pattern generator, the third test bytes to the first test circuits according to the first control signal; and
sequentially generating, by the second column test pattern generator, the fourth test bytes to the second test circuit according to the second control signal.

22. The test method according to claim 13, further comprising:
enabling the first test circuit array to have a plurality of first test partitions and the second test circuit array to have a plurality of second test partitions; and
respectively testing, by the second test circuits, that at least one test partition of the second test partitions has a connection line operating in an abnormal connection state according to the test results.
